(19) United States
(12) Patent Application Publication
(10) Pub. No.: US 2008/0297340 A1
(43) Pub. Date: Dec. 4, 2008

(54) Compliant Wireless Sensitive Elements and Devices

(76) Inventors: Dan O. Popa, Arlington, TX (US); Harry Stephanou, Arlington, TX (US); Shashank Priya, Arlington, TX (US)

Correspondence Address: ROSENBAUM & ASSOCIATES, P.C., 650 DUNDEE ROAD, SUITE #380, NORTHBROOK, IL, 60062, US

(21) Appl. No.: 11/754,890

(22) Filed: May 29, 2007

(51) Int. Cl. H01L 41/02; G08B 1/08; H01L 41/053

(52) U.S. Cl. 340/539.1; 310/317; 310/319; 310/345

(57) ABSTRACT

Sensitive elements and devices include at least one piezoelectric material and a compliant polymer substrate having elastomeric properties to lend flexibility without affecting sensitivity of the element and/or device. Sensitive elements are in operable communication with a control system; communication is wireless. Interaction of a sensitive element/sensitive device with an operator/environmental object/device is provided through use of an impedance controller and filter.

### BACKGROUND OF THE INVENTION

This invention relates in general to elements and devices with piezoelectric properties, such sensitive elements and devices for use, generally, when interacting with an operator or the environment, such as with assist devices or robots.

Present technology for machined apparatus, such as assist devices and robots, use discrete load cells for sensing and to interact with a human operator. So-called skins have been identified for use with these apparatus, but none have yet been commercialized; those under investigation have sensitivities based on infrared, radio frequency or organic field-effect transistor (FET) arrays. None are wireless or self-powered.

### SUMMARY OF THE INVENTION

Based on the above-mentioned inadequacies, herein are described, in one or more embodiments, small sensitive elements and devices with improvements that unexpectedly overcome one or more of the inadequacies.

Sensitive elements and devices described generally comprise piezoelectric materials and a non-rigid substrate. When desired, the substrate further comprises elastomeric properties to lend flexibility without affecting sensitivity therein to the elements and devices. Piezoelectrics provides multisensory and energy harvesting features to elements and devices herein. Sensitive elements/devices are in operable communication with a controller and incorporate wireless, self-powered features. A sensitive element or device as described is preferably in communication with, manipulated or controlled through a real-time feedback control system. Interaction with the environment relies on output from the sensitive element/device and/or the control system.

As described, each sensitive element or device may include one or more piezoelectric materials and as many as tens of thousands of units, each of which is preferably self-contained and self-powered. Each piezoelectric unit is small and compact, making it easy to use and of low-cost. When provided in a sensitive element or device herein, the one or more piezoelectric units define functionality of the element or device. A piezoelectric unit may impart one or a number of functions to the sensitive element/device described. When desired, it may also drive a sensitive element or device

In practice, a sensitive element or device may stand alone or incorporate any number of sensitive elements (e.g., in to a device). Each sensitive element in a device may have the same or offer one or more different functions.

In one or more embodiments, one or more sensitive elements are fitted with an adhesive material and/or removable strip to provide easy contact and/or removal. A sensitive element may be further provided with added sensors and/or materials, such as materials that affect material properties of the compliant substrate or functionality of the sensitive element.

In several embodiments, sensitive elements are adapted to new and/or to retrofit legacy robots and intelligent assist devices (IADs). IADs as described herein include those provided in a manufacturing line, entertainment industry, household products, automobiles, as examples. Sensitive elements may also be fitted to loads carried by IADs/robots to provide contact information with the environment (e.g., other objects). Such sensitive elements are particularly suitable to prevent injuries as well as improve sensitivity/dexterity/rotation/motion of an apparatus or machine in which they are incorporated. Multisensing and processing of sensitive elements/devices and/or LADS fitted with sensitive elements are coordinated with supervisory decision-making controller. Such control allows multisensory processing and hence provides multifunctioning (e.g., in the form of microbalance, micromovement, and ultra fine focusing) to a sensitive element/device and/or LAD.

The ease and adaptability of sensitive elements and devices provided herein allow them to be modified for given requirements. Ease and adaptability are provided by virtue of the unexpected flexibility of the sensitive elements/devices as invented herein. The previously undisclosed combination without undue experimentation. Sensitive elements may be fitted for one or more particular functions with additional features described herein. Consequently, sensitive elements may be modified in a predetermined fashion without affecting overall design, while allowing tuning of functional parameters as needed (e.g., size, weight, number, arrangement, electrical connections, power storage scheme, power production, degree of response, and overall layout and packaging). Sensitive elements and devices herein are not only adaptive, they are also cost-effectiveness and easy to assemble.

Those skilled in the art will further appreciate the above-noted features and advantages of the invention together with other important aspects thereof upon reading the detailed description that follows and in conjunction with the drawings.

### BRIEF DESCRIPTION OF THE DRAWINGS

For a more complete understanding of the present invention and the advantages thereof, reference is now made to a description, taken in connection with the accompanying figures, wherein:

FIGS. 1A and 1B depict representative schematics of embodiments of sensitive elements described herein;

FIGS. 2A and 2B depict representative schematics of additional embodiments of sensitive elements described herein;

FIG. 3 depicts representative images of (A) a substrate, (B) a sensitive element comprising a compliant substrate and a plurality of piezoelectric units, and (C) a highly flexible substrate housing a plurality of piezoelectric units;

FIG. 4A depicts in schematic form a representative algorithm for signal processing;

FIG. 4B illustrates a representative loading condition;

FIGS. 5A-G depict representative outputs for different forces applied on an element embodied herein;

FIG. 6 depicts a representative response of a sensitive element embodied herein after loading and unloading;

FIG. 7 depicts output of a representative sensitive element after a single touch;

FIG. 8 depicts a representative sensitive element on an assist device

FIG. 9 depicts a representative control system described herein;

FIG. 10 depicts a representative IAD in schematic form;

FIG. 11 depicts another representative control system described herein;

FIG. 12 depicts a representative raw signal from a sensitive element similar to that positioned as in FIG. 8; and

FIG. 13 depicts representative force estimation for the same sensitive element of FIG. 12;

FIGS. 14A-C depict representative outputs for different forces applied on an element embodied herein;

### DETAILED DESCRIPTION OF THE INVENTION

Although making and using various embodiments are discussed in detail below, it should be appreciated that the present invention provides many inventive concepts that may be embodied in a wide variety of contexts. The specific aspects and embodiments discussed herein are merely illustrative of ways to make and use the invention, and do not limit the scope of the invention.

In the description which follows like parts may be marked throughout the specification and drawing with the same reference numerals, respectively. The drawing figures are not necessarily to scale and certain features may be shown exaggerated in scale or in somewhat generalized or schematic form in the interest of clarity and conciseness.

As described herein are sensitive elements, each comprising at least one piezo material with a non-rigid substrate, energy harvesting capabilities and wireless communication features. In some embodiment, one or more piezoelectric units with a substrate further comprise a micro electrical mechanical systems (MEMS) drive and control circuit. Sensitive elements may be very small, such as 1 mm² or less, and may reach sizes greater than 1 cm². Generally, there are no size restrictions because functionality and use will factor into size decisions. Such decisions will be readily apparent as they are preferably based on overall design features and will require no undue experimentation.

The substrate herein comprises generally any non-rigid material or a compliant material. Compliance does not require flexibility; however, in some embodiments, the substrate is an elastomeric material or elastomeric polymer with good elongation and/or high performance property. The polymer may behave as an electret, which may or may not offer additional advantages to the sensitive element or device herein. In one or more embodiments the substrate is a silicone elastomer or silastic elastomer. Other suitable elastomeric materials include but are not limited to silicone rubber, natural rubber, organic rubbers, and elastomers of neoprene, fluorocarbon, urethane, polyacrylate, ethylene/acrylate, butyl, ethylene-propylene-diene monomer, copolymer of styrene and butadiene, and nitrile,

In some embodiments the substrate is porous. When desired, the substrate may serve as an outer layer or surface feature, such as when provided as a surface sensor. Suitable substrates are transparent or colored and may further include performance-related properties, such as a wide temperature range, high tear strength, abrasion resistance, air permeability, steam permeability, resistance to weathering and/or high tensile strength. Such properties do not have to reside in the same substrate, such that multiple substrates may be combined or layered to offer any number of desired properties. Additional features that are useful with sensitive elements/devices herein may also reside in a single substrate or in multiple substrates, provided as layers. Such added features include electrical interconnects or components, antenna for wireless communication, controller, additional sensors (e.g., for temperature, proximity, sound as examples), insulation and/or hydrophobicity.

The antenna is configured for predictable frequency output. Electrical interconnects/components may address one or a number or sensitive elements and may be for signal conditioning and/or wireless transmission and/or serve as an electrical source/driver. When desired, electrical insulation or hydrophobicity may be imparted by one or more suitable substrates. In addition and when suited, a hierarchical arrangement of one or more heterogeneous layers may provide multiple functionalities to sensitive elements and devices described herein.

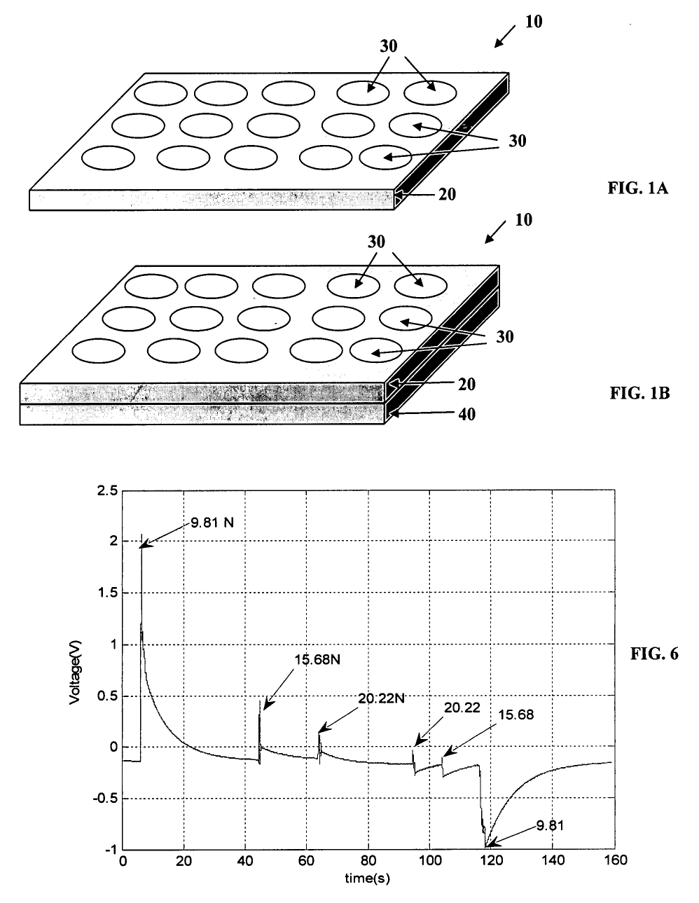

FIGS. 1A and 1B are representative schematics of sensitive elements 10 described herein comprising substrate 20 and a plurality of piezoelectric units 30 therein. FIG. 1B further comprises layer 40, which may include one or more additional substrates as layers, such layers comprising an electrical insulator, a hydrophobic layer, an adhesive layer, electrical interconnect/components, antenna, glue electronics, additional sensors and any combination therein. Layer 40 may reside as a single layer or be provided as a plurality of additional layers, each comprising one or more of the features/functionalities described (e.g., electrical insulator, hydrophobic layer, adhesive layer, electrical interconnects/components, antenna, glue electronics, additional sensors). Thickness of a compliant substrate, as well as the sensitive elements formed therefrom, are limitless. A minimum thickness of a compliant substrate is typically at or about 2 mm. Thickness of a compliant substrate often depends, in part, on the material and/or compliance of the substrate, itself.

A piezoelectric unit as described herein is typically one or more piezoelectric materials in a configuration optimized and preferably calibrated for a particular application (e.g., force, pressure, deformation/displacement, acceleration, vibration, sound, strain, as examples). A piezoelectric material provides an element/device with sensitivity, such as to force, pressure, deformation, displacement, acceleration, vibration, sound, strain, motion, heat, voltage, chemicals, as examples. A piezoelectric material provides interaction cues between a sensitive element/device and its environment and measurement/details about the environment.

In one or more embodiments, a piezoelectric unit may further comprise an active region and an inactive region (e.g., layers, fibers, surfaces). Examples of preferred piezoelectrics are piezoelectric fiber composites (or active fiber composites), piezoelectric multilayer composites, and unimorphs. The active region comprises a useful piezoelectric material, such as those known to one of ordinary skill in the art. The piezoelectric unit may be further provided/configured/associated with an actuator (voltage), switch (pressure), motor, ultrasonic device (proximity), or other sensor (heat, chemical, color, linear, pressure, force, load, vibration, as examples). Thus, a sensitive element responds, detects, predicts, and/or generates output. Output is typically communicated to an antenna.

Piezoelectric units are typically provided as part of the compliant substrate and may be positioned as desired and where function is of most value. The architecture and material properties of the substrate and piezoelectric units provide sensitive elements and devices herein with an ability to stretch and/or move without degradation in functionality. Piezoelectric units need not be identical; however, calibration of the one or more portions is typically performed in order for proper functionality.

Functionality helps determine not only a size of a sensitive element, also how many piezoelectric units will be provided with a substrate. As few as one piezoelectric unit and as many as tens of thousands of piezoelectric units may be incorporated in a sensitive element and the compliant substrate thereof. The compliant substrate and overall functionality of the sensitive element may each and/or both help suggest a number and/or size of one or more piezoelectric units. In one or more embodiments, piezoelectric units are very small, and may be as small as 1 mm³. In several preferred embodiments, a piezoelectric unit is less than or about 10 mm in diameter and 0.1 mm thick. Generally, piezoelectric units are not thicker than the compliant substrate.

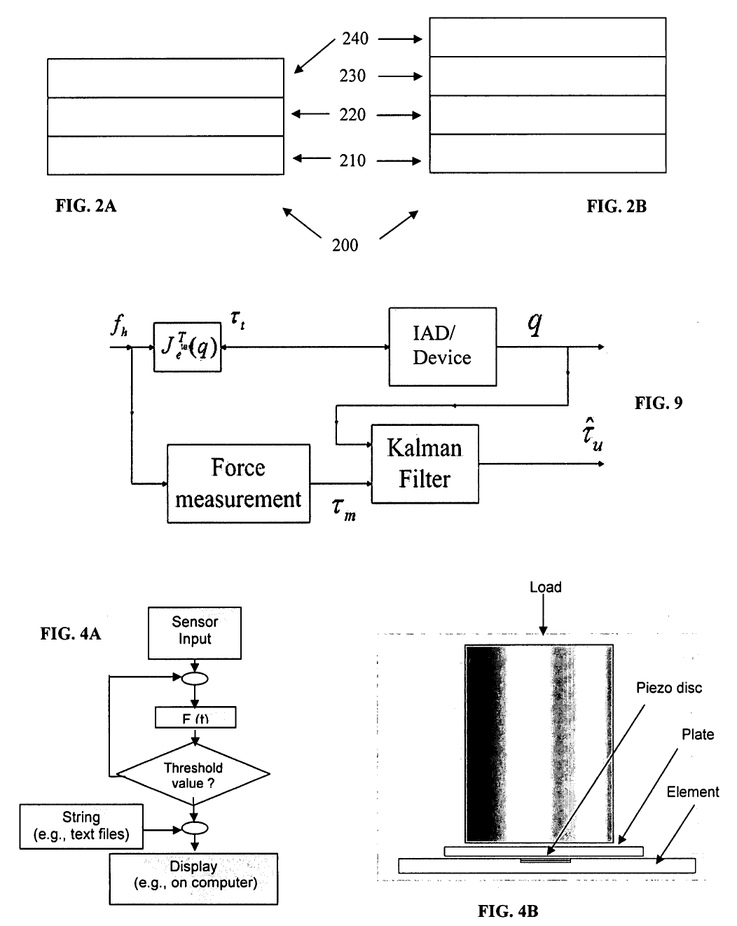

FIGS. 2A and 2B illustrate additional representative elements 200 as described herein. Layer 210 represents a substrate and one or more piezoelectric units. Layer 210 may further comprises additional sensors or actuators that can be piezoelectric, electromagnetic or of a suitable make-up. Layer 220 comprises electrical contacts. Layer 230 comprises an antenna. Layer 240 comprises a hydrophobic layer, insulation layer and/or adhesive layer. Having layer 240 as a surface adhesive, provides a sensitive element herein with ease in application and/or removal apply.

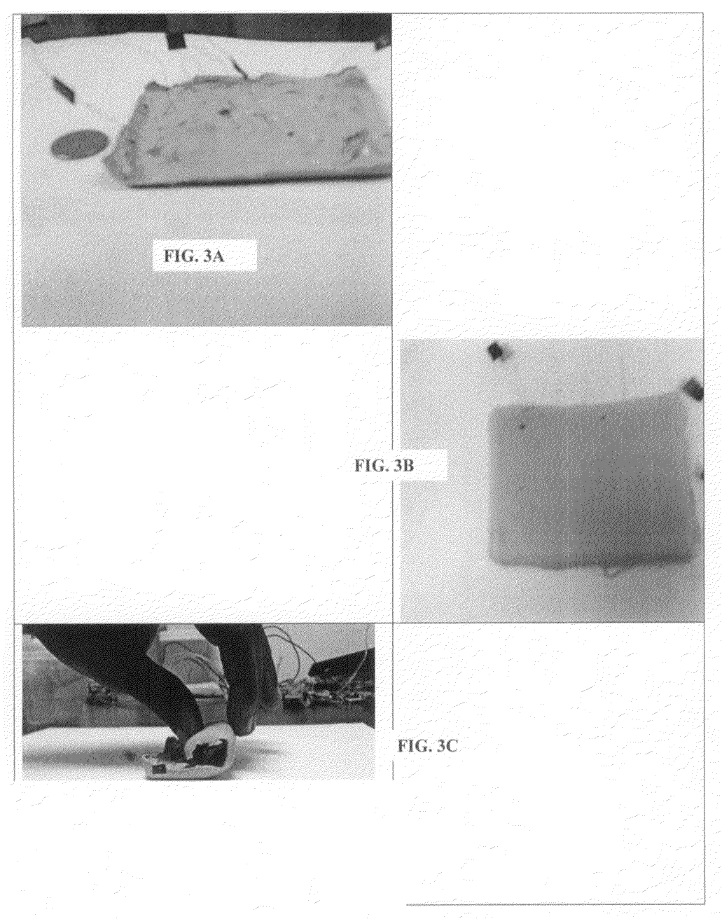

In one or more embodiments, a sensitive element/device described herein comprises a compliant substrate, novel MEMS sensors, an antenna and controller. Examples of a fabricated sensitive element are shown in FIGS. 3A-3C comprised of a compliant substrate, a plurality of piezoelectric units and further outfitted with electrical interconnects, motors, and antenna for sensing and actuation.

Referring still to FIG. 3, the substrate shown was fabricated with a compliant material of room-temperature vulcanizing (RTV) silicone rubber and had a dimension of 65×80 mm² and was, on average, 3 mm thick. Fabrication was low-cost. Low profile piezoelectric unimorphs, each having dimensions and characteristics as shown in TABLE 1, were cast in the substrate. Unimorphs were cast in an array with a blend of RTV silicone. A solution using a commercially available thinner was added to further improve softness of the silicone substrate. Five unimorphs, with 15 mm spacing between them, were embedded in the compliant substrate as shown representatively in FIGS. 3A (lower surface) and 3B (upper surface). FIG. 3C illustrates the continued flexibility of the fabricated sensitive element; the substrate was able to bend to a radius of at least about 8 mm. Electrical interconnects were provided by lamination to a second, typically flexible or compliant, non-rigid substrate. For the example, a polyimide sheet contained electrical traces directed to additional electrical circuits that further provided signal conditioning, addressed multiplexing and data transmission to the antenna layer.

TABLE 1
Specifications of a representative piezoelectric unit.

| Parameter | Value |
|---|---|
| Dimension (mm) | Φ10 × 0.2 |
| Resonance Frequency (kHz) | 2.6 ± 0.5 |
| Capacitance (pF) | 160,000 |
| Operating Temperature (° C.) | −20 to 70 |

Piezoelectric units as depicted in FIG. 3 were unimorph transducers comprising a piezoelectric disc bonded to a brass disc. The diameter of each piezoelectric disc was 8 mm, fabricated using a soft piezoelectric (PZT) material based on a composition comprising Pb(Zr_{0.52}Ti_{0.48})O₃—Pb(Zn_{1/3}Nb_{2/3})O₃. The small size of each unimorph allowed it to be embedded inside the substrate without hampering flexibility of the substrate. A piezoelectric unimorph as depicted in FIG. 3 provides a number of advantages, including low profile, light weight, fast response, and high capacitance. Alternate and/or additional piezoelectric units providing similar characteristics may also be used and/or substituted. Any piezoelectric unit provided with sensitive elements herein typically do not require an input voltage. This is contrasted with sensors typically used, such as those that respond by a change in resistance or capacitance and require a processing circuit to communicate with a second device.

Characterization of a sensing action of a sensitive element of FIG. 3 was performed using an automated data collection system. A signal from the sensor was provided to a personal computer interconnect/peripheral component interconnect (PCI) card. In this case, the card was capable of 64 analog inputs with a 16 bit AD converter. Signal processing was programmed for output of the sensitive element when input exceeded a threshold value; such input would then trigger a computer to output a text string built into the program. The text string may also serve as a command for other sensors/actuators incorporated in a sensitive element or device. A representative algorithm of such a program is shown in FIG. 4A. Additional examples are also provided later.

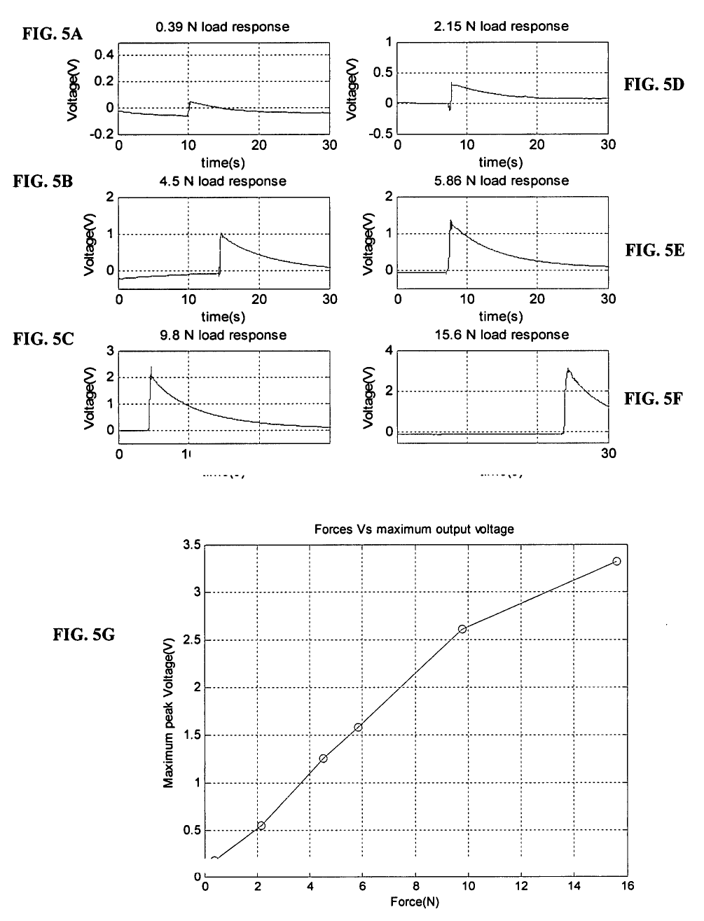

For understanding responsiveness and functionality of the sensitive element of FIG. 3, it was loaded on a flat plate (approximately 50×70 mm² area) as shown in FIG. 4B. Output pulses for various loads were recorded, as illustrate in FIGS. 5A-G, in which a constant load was applied on a single sensor (i.e., piezoelectric unimorph). The figures show output increased quickly with a very short rise time and decay depended on the magnitude of capacitance. The short response time re-affirms one of the advantages of using piezoelectrics with sensitive elements described herein.

A representative response under loading and unloading conditions is shown in FIG. 6. Initially a load of 9.81 N was applied for about 25-40 seconds. The load was then stepped up to 20.22 N. After holding at a maximum value the load was stepped down. Overall, output voltage was proportional to the gradient of stress in a non-hysteresis fashion for the range considered.

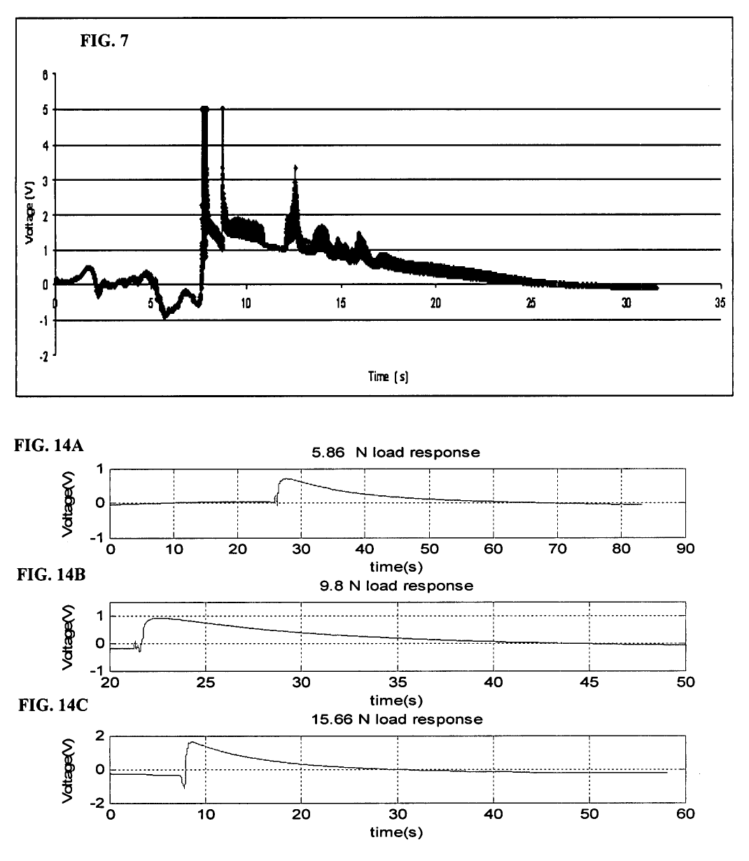

In response to hand touch, a representative output signal is illustrated in FIG. 7 showing output of a single sensor touched randomly. The sudden voltage of up to 5 V corresponded with a hand shake as an impulse stimuli. The repeatable output of 2 V was obtained with only slight touch. FIG. 7 demonstrates clearly a tactile sensing of a sensitive element described herein.

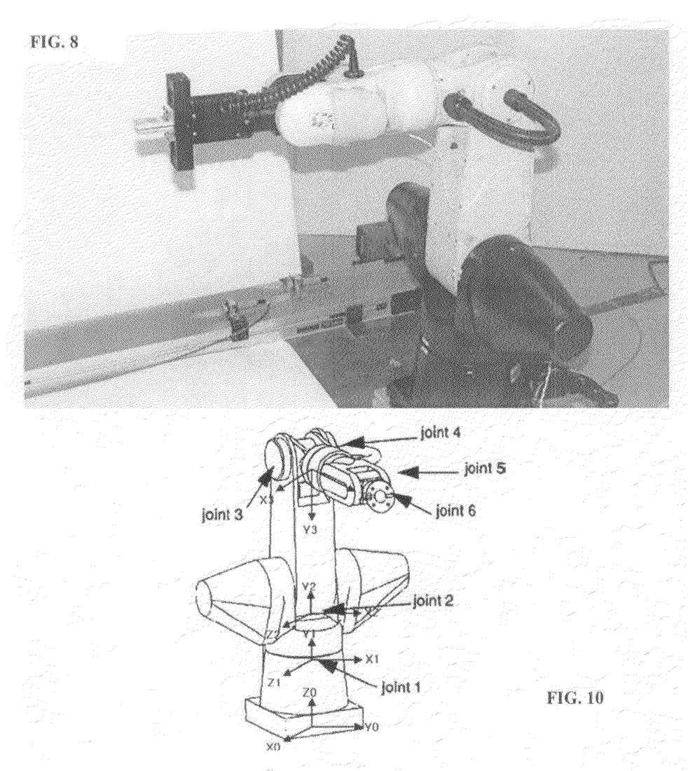

When suitable, a sensitive element comprises a substrate that mimics skin. As depicted in FIG. 8, a sensitive element comprising piezoelectric pressure sensors is provided as a surface feature for a robotic workcell. The substrate was of an artificial RTV silicone elastomeric material embedded with piezoelectric unimorphs.

In some embodiments, sensitive elements described herein behave similar to cutaneous and subcutaneous mechanoreceptors. When provided with a digital signaling processing chip, a sensitive element will identify/respond to one or more specific functionalities, such as touch and shock, as previously shown. When one or more sensitive elements are configured to form a sensitive device, actuation of particular anchor points are driven by actuators, such as ultrasonic motors.

A program for wireless control for sensitive devices and/or IADs comprising sensitive elements was created by the inventors to process signals from the sensitive element and to interact with sensitive element on the device. In some forms, sensing is a combination of force and proximity sensing as well as force estimation via piezoelectrics. In addition, or as alternatives, sensing may include a variety of capabilities, including proximity, thermal changes, color and chemical recognition, as examples. Piezoelectrics may, in part, provide accurate and measurable quantifications of such modalities.

In one or more embodiments, interaction of a sensitive element with an operator is provided through use of a Kalman filter and impedance controller. Work path plans are provided directly to a device/LAD/robot through a simple operator interface adapted to a sensitive element described herein. An example is provided in FIG. 9. In FIG. 9, the interaction is force. Other suitable interactions may also be measured. Guidance of the device/IAD is provided by training autonomous and cooperative skills without using a pendant.

Using force as an example and referring to a robot as depicted in FIG. 10, a representative algorithm for interaction using a sensitive element when configured with a device/robot and coupled to an operator is based on link coordinates (X₀, Y₀, Z₀) and coordinates for the first three links (Xᵢ, Yᵢ, Zᵢ, where i=1 to 6). A point of interaction, P, also referred to as virtual end effector may be anywhere. Using the product of an exponentials formula, a forward kinematics map from the robot base to a point P of application of force is gₛₜ:Qx [symbol] ³→SE(3), and given by Equation 1

$${g}_{st} ( q , p ) = ( {{∐}^{j}}_{i = 1} {e}^{{\hat{ξ}}_{i} {q}_{j}} ) {g}_{st} ( 0 , p ) , , \qquad ( 1 )$$

where j is the robot link where the force is applied, qᵢ's are joint coordinates, and ξᵢ's are the link twists given by Equation 2:

$${ξ}_{i} = [ \begin{matrix}- {ω}_{i} \times {v}_{i} \\ {ω}_{i}\end{matrix} ] , \qquad ( 2 )$$

where ωᵢε [symbol] ³ is a unit vector in the direction of the twist axis and vᵢε [symbol] ³ is a point on the axis.

For an robot of FIG. 10, the first three twists are given by:

$$\begin{matrix}{ω}_{1} = {[ 0 , 0 , 1 ]}^{T} , {ω}_{2} = {[ 0 , 0 , 1 ]}^{T} , {ω}_{3} = {[ 0 , 1 , 0 ]}^{T} \\ {v}_{1} = {[ 0 , 0 , 0 ]}^{T} , {v}_{2} = {[ 0 , 0 , {d}_{1} ]}^{T} , {v}_{3} = {[ 0 , 0 , {d}_{1} + {d}_{2} ]}^{T}\end{matrix} ,$$

where dᵢ, is the link length of the i^{th} joint. The transformation between base and virtual end-effector frames at q=0 is given by Equation 3:

$${g}_{st} ( 0 , p ) = [ \begin{matrix}I & ( \begin{matrix}0 \\ {d}_{3} \\ {d}_{1} + {d}_{2}\end{matrix} ) \\ 0 & 1\end{matrix} ] , , \qquad ( 3 )$$

if point p is close to the base of the robot wrist, and therefore j=3.

In general, a base to virtual end-effector transformation matrix is Equation 4:

$${g}_{st} ( q , p ) = [ \begin{matrix}{}_{j + 1}^{0} R ( q ) & p ( q ) \\ 0 & 1\end{matrix} ] .. \qquad ( 4 )$$

At the same time, the relationship between Jacobian expressed in base frame and Jacobian expressed in virtual end-effector frame is Equation 5:

$${}^{0} J ( p , q ) = \frac{\partial p ( {q}_{1 … j} )}{\partial {q}_{1 … j}} = {}_{j + 1}^{0} R ( q ) {J}_{e} ( p , q ) , , \qquad ( 5 )$$

where j^{th} frame is a virtual end-effector frame. Therefore the Jacobian expressed in the virtual end-effector frame may be obtained from Equation 6:

$$\begin{matrix}{J}_{e} ( p , q ) = {}_{0}^{j + 1} R ( q ) {}^{0} J ( q ) \\ = {( {}_{j + 1}^{0} R ( q ) )}^{T} {}^{0} J ( q ) , ,\end{matrix} \qquad ( 6 )$$

where Jₑ(q) is a Jacobian expressed in the virtual end-effector frame. Because forces acting on the manipulator are measured in the end-effector frame, Jₑ(p,q) is used in manipulator dynamics.

A dynamical model of a manipulator of FIG. 10 is provided as Equation 7:

$$M ( q ) \ddot{q} + C ( q , \dot{q} ) \dot{q} + D \dot{q} + {f}_{c} ( \dot{q} ) + G ( q ) = τ + {J}_{e}^{T} ( p , q ) {f}_{h} , \qquad ( 7 )$$

where qε [symbol] ⁿ is a vector of generalized joint coordinates, n is a number of joints, M(q)ε [symbol] ^{n×n} is a symmetric positive definite mass (inertia) matrix, C(q,\dot{q})\dot{q}ε [symbol] ⁿ is a vector of Coriolis and centripetal forces, G(q)ε [symbol] ⁿ is a vector of gravitational torques, Dε [symbol] ^{n×n} is a positive semi definite diagonal matrix for joint viscous friction coefficient, f_{c}(\dot{q})ε [symbol] ⁿ is a Coulomb friction term, τε [symbol] ⁿ is a vector of generalized torques acting at the joints, Jₑ(p,q)ε [symbol] ^{3×n} is a conventional Jacobian to the virtual end-effector P expressed in the end-effector frame and fₕε [symbol] ³ is an operator-robot interaction force at the virtual end-effector represented in its frame.

Assuming that force measurement at the end-effector or the virtual end-effector (where a sensitive element herein is positioned) is available only in one dimension or less (no measurement at all). An Extended Kalman Filter, as a way to estimate torques acting at the joints due to pushing force at the virtual end-effector, is applied. For a case when interaction occurs on a 3rd link, j=3, a dynamical model of the manipulator only from the base to the end-effector is Equation 8:

M(q)\ddot{q}+N(q,\dot{q})=τₘ+τᵤ (8),

where qε [symbol] ^{j}, N(q,\dot{q})=C(q,\dot{q})\dot{q}+D\dot{q}+fₑ(\dot{q})+G(q), and τₘ=τ+Jₑ^{T}(q)fₘε [symbol] ³ is a known torque acting at a joint (either through direct measurement or from control input), τᵤ=Jₑ^{T}(q)fᵤε [symbol] ³ is a unknown torque to be estimated (due to pushing force in directions that cannot be measured). Since a sensitive element is used to measure force perpendicular to the manipulator, it is assumed that fₘ=[fₘₓ,0,0]^{T}, i.e., only a force element in x direction may be measured.

The state-space model of Equation 8 is Equation 9:

$$\dot{z} = [ \begin{matrix}\dot{q} \\ \ddot{q}\end{matrix} ] = [ \begin{matrix}\dot{q} \\ {M ( q )}^{- 1} [ {τ}_{m} + {τ}_{u} - N ( q , \dot{q} ) ]\end{matrix} ] .. \qquad ( 9 )$$

To include unknown torque vector into the estimation, a new extended state x is used and includes the unknown torque vector τᵤ, provided as Equation 10:

x=[q^{T}\dot{q}^{T}τᵤ^{T}]^{T}εR^{2j+3} (10).

From Equation 8, τᵤ may be referenced using Equation 11:

τᵤ=M(q)\ddot{q}+N(q,\dot{q})−τₘ (11).

Since τᵤ is a time-varying function, the first order time derivative \dot{τ}ᵤ are Equations 12/13:

$$\begin{matrix}{\dot{τ}}_{u} = \frac{d}{d t} [ M ( q ) \ddot{q} + N ( q , \dot{q} ) - {τ}_{m} ] , or ; & ( 12 ) \\ {\dot{τ}}_{u} = \dot{M} \ddot{q} + M ( q ) {q}^{…} + \dot{N} - {\dot{τ}}_{m} . & ( 13 )\end{matrix}$$

A new augmented state-space model is Equation 14:

$$\begin{matrix}\dot{x} = [ \begin{matrix}\dot{q} \\ \ddot{q} \\ {\dot{τ}}_{u}\end{matrix} ] \\ = [ \begin{matrix}\dot{q} \\ {M ( q )}^{- 1} [ {τ}_{m} + {τ}_{u} - N ( q , \dot{q} ) ] \\ \dot{M} \ddot{q} + M ( q ) {q}^{…} + \dot{N} - {\dot{τ}}_{m}\end{matrix} ] \\ = f ( x , {τ}_{m} ) , where\end{matrix} \qquad ( 14 )$$

f(x,τₘ) is a nonlinear representation of the new augmented state-space model (Equations 15/16/17),

$$\begin{matrix}\dot{M} = \frac{d}{d t} ( M ( q ) ) , & ( 15 ) \\ \dot{N} = ( \frac{d}{d t} C ( q , \dot{q} ) ) \dot{q} + C ( q , \dot{q} ) \ddot{q} + D \ddot{q} + \frac{d}{d t} [ {f}_{c} ( \dot{q} ) ] + \frac{d}{d t} [ G ( q ) ] , & ( 16 ) \\ {\dot{τ}}_{m} = \frac{d}{d t} {τ}_{m} ( t ) .. & ( 17 )\end{matrix}$$

In order to convert a continuous augmented state-space model into a discrete model, Equation 14 needs to be discretized. A first order discretization of Equation 14 with sampling time T leads to Equation 18:

$${x}_{k + 1} = {f}_{T} ( {x}_{k} , {τ}_{mk} ) + [ \begin{matrix}{v}_{k} \\ {η}_{k}\end{matrix} ] , \qquad ( 18 )$$

where f_{T}(xₖ,τₘₖ)=xₖ+\dot{x}(xₖ,τₘₖ)T, vₖε [symbol] ^{2j} is process white noise, and ηₖε [symbol] ^{j} is also process white noise associated with unknown torque. Note that a process noise ηₖ is used to introduce measurement noise from the sensor portion of the sensitive element. An overall state covariance matrix is now Equation 19:

$$Q = E ( {[ \begin{matrix}{v}_{k} \\ {η}_{k}\end{matrix} ] [ \begin{matrix}{v}_{k} \\ {η}_{k}\end{matrix} ]}^{T} ) .. \qquad ( 19 )$$

Observation equation from the robot joint encoders is given by Equation 20:

yₖ=Cxₖ+wₖ (20), where

C=└I₂ⱼ 0_{j×j}┘, wₖε [symbol] ^{2j} is a measurement white noise with covariance (Equation 21):

$$\begin{matrix}R = E ( {w}_{k} {w}_{k}^{T} ) .. \\ Then to define & ( 21 ) \\ \begin{matrix}{F}_{x} ( x , {τ}_{m} ) = \frac{\partial {f}_{T} ( {x}_{k} , {τ}_{mk} )}{\partial x} ∈ {ℜ}^{( 2 j + 3 ) \times ( 2 j + 3 )} \\ = [ \begin{matrix}\frac{\partial {f}_{T} ( {x}_{k} , {τ}_{mk} )}{\partial q} & \frac{\partial {f}_{T} ( {x}_{k} , {τ}_{mk} )}{\partial \dot{q}} & \frac{\partial {f}_{T} ( {x}_{k} , {τ}_{mk} )}{\partial {τ}_{u}}\end{matrix} ] ,\end{matrix} & ( 22 )\end{matrix}$$

to be a Jacobian matrix of f_{T}(x,τₘ) with respect to [q^{T} \dot{q}^{T} τᵤ^{T}]^{T}. Instead of a signum function in a f_{c} Coulomb friction term, a smooth hyperbolic tangent function tan h( ) is applied, so a partial derivative of Equation 220 is well defined (e=Equation 23):

f_{c}(\dot{q})=μ tan h(α\dot{q}), (23). Where

μ is a friction coefficient, α is a design constant chosen to be larger than a desired HRI force bandwidth. An Extended Kalman Filter is now used to estimate a state of a linearized system in two steps (Equations 24 and 25 followed by Equations 26, 27 and 28:

(a) Time Update: \hat{x}ₖ₊₁⁻=f(\hat{x}ₖ,τₘₖ) (24);

Pₖ₊₁⁻=FₓPₖFₓ^{T}+Q (25).

(b) Measurement Update: Kₖ₊₁=Pₖ₊₁⁻C^{T}[CPₖ₊₁⁻C^{T}+R]⁻¹ (26);

Pₖ₊₁=Pₖ₊₁⁻−Kₖ₊₁CPₖ₊₁⁻ (27);

\hat{x}ₖ₊₁=\hat{x}ₖ₊₁⁻+Kₖ₊₁(yₖ₊₁−C\hat{x}ₖ₊₁⁻) (28),

where Pₖ₊₁⁻ε [symbol] ^{2j+3)×(2j+3)} is a covariance matrix of a prediction error, Pₖ₊₁ε [symbol] ^{(2j+3)×(2j+3)} is a covariance matrix of an estimation error.

Assuming a pushing force may be estimated by a Kalman Filter, it is desirable to make use of it in order to guide motion of a manipulator. An impedance control scheme is implemented to program robot compliance. This specifies a desired compliance characteristic of a manipulator of the robot so that when an operator applies force to the robot, it feels as if the robot has certain mass and viscous coefficient. Define the desired impedance of an robot manipulator from its base to link j as Equation 29: M_{d}\ddot{q}_{cd}+B_{d}\dot{q}_{cd}+K_{d}q_{cd}=τᵢ (29), where τᵢε [symbol] ^{j} is a total torque due to pushing force. τᵢ is written as Equation 30:

τᵢ=Jₑ^{T}(q)fₘ+Jₑ^{T}(q)fᵤ, (30),

where Jₑ^{T}(q) is defined in Equation 6, fₘ and fᵤ are defined in Equation 8, M_{d}ε [symbol] ^{j×j} is a desired Mass (Inertia) matrix, B_{d}ε [symbol] ^{j×j} is a desired Damping matrix, K_{d}ε [symbol] ^{j×j} is a desired stiffness matrix, and q_{cd} is a desired angular position of the manipulator.

The relationship between desired angular, position, velocity and acceleration and M_{d}, B_{d} and K_{d} may be written in matrix form as shown in Equation 31:

$$[ \begin{matrix}{\dot{q}}_{c d} \\ {\ddot{q}}_{c d}\end{matrix} ] = [ \begin{matrix}{0}_{n \times n} & {I}_{n \times n} \\ - {M}_{d}^{- 1} {K}_{d} & - {M}_{d}^{- 1} {B}_{d}\end{matrix} ] [ \begin{matrix}{q}_{c d} \\ {\dot{q}}_{c d}\end{matrix} ] + [ \begin{matrix}{0}_{n \times 1} \\ {M}_{d}^{- 1} {τ}_{l}\end{matrix} ] .. And , \qquad ( 31 )$$

Equation (31) can be solved numerically to find q_{cd}, \dot{q}_{cd} and \ddot{q}_{cd}.

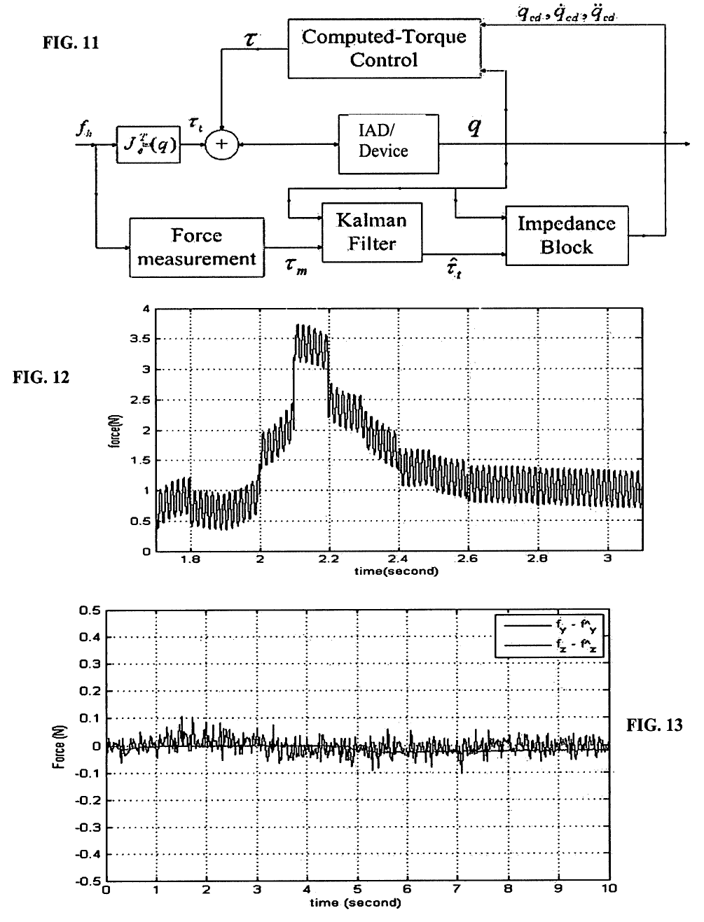

A straightforward/standard computed-torque controller to provided track the desired manipulator trajectory q_{cd} with an overall scheme shown in FIG. 11. From Equation 8 is the following (Equation 32), M(q)\ddot{q}+N(q,\dot{q})=τ+Jₑ^{T}(q)fₘ+Jₑ^{T}(q)\hat{f}ᵤ (32), where \hat{f}ᵤ is obtained from estimation of the unknown torque. The control signal becomes Equation 33:

τ=M(\ddot{q}_{cd}−u)+N−Jₑ^{T}(fₘ+\hat{f}ᵤ), (33), where

u=−Kᵥ(\dot{q}_{cd}−\dot{q})−Kₚ(q_{d}−q), (34), and Kv

and Kₚ are PD controller gains.

An example of raw unfiltered signal measured from a sensitive element configured similar to that shown in FIG. 8 is illustrated in FIG. 12. With the algorithm described above, force estimation is improved significantly as illustrated in FIG. 13. With this example, only a one-dimensional measurement of the system was made, showing some noise.

As another example, one or more sensitive elements described herein are provided with new IAD/robot platforms in a cooperative manipulation system. Such a platform is mobile and/or humanoid. The system is modular and scalable, capable of being scaled up, for example, as a large device for carrying heavy loads by using multiple basic working groups together (like a crew) or scaled down, for example, for intricate/articulated performance, such as surgical procedures. The system may further comprise enhanced dexterity/multifunctional end-effectors (e.g., snake/robotic arm for complex operations/surgery, including grippers, manipulators, vacuum cup tooling, pneumatic/electric motors, deburring tools, peripheral tools). Such a system will preferably include variable stiffness levels accomplished by a combination of bracing and reconfiguration to carry out accurate/precision tasks. Interaction with an operator is provided via direct touch, simple path planning interfaces. Consequently, a sensitive element and device herein will endow a sensitive device/LAD/robot or other suitable device or subject having the sensitive element with one or more qualities considered humanistic, such as a sense of caution and awareness of surroundings.

For example, an LAD/device/robot may now, with sensitive elements described herein, have improved performance features, such as an enhanced safety mode, a precision assist mode, as well as a large motion guided mode.

In yet another example, a macro fiber composite (MFC) comprising uniaxially aligned fibers surrounded by a polymer matrix with an interdigital electrode pattern was embedded in an RTV silicone compliant substrate, Output for various normal load forces on a flat plate (as described with FIG. 4B) were measured; representative examples are shown in FIGS. 14A-C, indicating that an output voltage of up to 1.8V is provided with a normal force of 15 N.

MFCs used herein are typically machined from low-cost piezoelectric ceramic wafers and can be operated in either d₃₃-mode or d₃₁-mode by designing two different electrode patterns. MFC operating in d₃₃-mode have a higher energy conversion rate but lower electrical current as compared to operation in a d₃₁-mode. Due to its high d₃₃ constant, a large strain value as high as 4500 ppm may be obtained. MFCs, as transducers, have been shown to have a reliability of over 10⁹ cycles operating at maximum strain. MFCs offer similar advantages as previously described by having a low profile, light weight and flexibility.

By incorporating multiple sensitive elements with desired functionalities, an augmented controller adapted to such sensitive elements will create desired interactive behaviors between the subject/device/IAD having the sensitive elements and its environment and/or between the subject/device/IAD having the sensitive elements and an operator. Importantly, a sensitive element and sensitive device will detect and avoid damaging contact with an operator or environmental obstacles.

As described, a controller provides multisensor processing of a robot/LAD/device having one or more sensitive elements. Real time processing, decisions and complex events are performed. A control system herein will allow one or more behaviors/operations to be programmed into the robot/IAD/device and selected based on readings obtained from sensitive elements incorporated on the robot/IAD/device. The controller, in a manner similar to a programmable logic controller, has multiple input and output arrangements, among other favorable features. However, as described, the controller is typically not as simple. It generally requires an algorithm, especially with very high speed and precision controls. The controller may be in operable communication with additional external input/output modules and/or a computer or computer network.

Actuation of sensitive elements described are selected, in part on function, size, and condition of use. For example, when a sensitive element is sensing force, selection is dependent, in part, on a force-displacement requirement. Additional factors that influence actuation selection are weight, size, driving and control circuitry, mounting mechanism, and cost. Conformal actuators or motors are further selected based on capabilities under dynamic stresses, temperature and pressure, and linearity.

Micro actuators are preferred, preferably those offering finite anchor-control at a low voltage (e.g., typically not more than 30 V), high strain, high power density, robustness and durability, and support of fully developed adjunct technology (fasteners, drivers, etc.). Additionally, the actuator must have longevity (in a range of 10⁵ cycles or greater), a sufficient force generation (e.g., up to or greater than 15 times the weight of the actuator), up to 200 grams or better at low power levels (50-100 mW), and have a short response time (e.g., preferably about 1 millisecond, with a speed of actuation at least about 5 cm/sec or 2 in/sec). The actuators should also preferably be dry and/or thoroughly sealed and inexpensive.

Current actuators based on electromagnetic control will not satisfy these requirements. On the other hand, piezoelectric actuators have fast response time, high generated force per unit area and high resolution in displacement. They may be miniaturized and still provide excellent control over motion. Other advantages associate with a piezoelectric motor includes a large energy storage, no electromagnetic noise generation, high efficiency, non flammable nature, and safe in overload and short circuit conditions. Compared with others, such as magnetostrictive actuators and shape memory alloys, piezoelectrics have further advantages as a two-way drive, not requiring magnetic shielding or a heat source and maintaining stable operation over a prolonged period of time. Preferred piezoelectric actuators/motors offer high precision and combine unlimited stroke with high resolution in a compact dimension and provide a linear response to input voltage.

As described, sensitive elements and devices herein are self-powered and communicate wirelessly. With fusion of multiple elements and a control module, a sensitive element/device may readily interact with one or more operators, humans, or obstacles (its environment). Sensitive elements and devices include additional advantageous features such as adhesive or insulation properties, flexibility, simplistic fabrication, self powered sensing (no need of external voltage), natural look, and low profile.

Sensitive elements may reside on any surface, including gloves, clothing, outerwear, an assist device/robot/IAD, as examples. In addition, communication from one or more sensitive element may be transferred from a sensitive element to a second device (e.g., operator, assist device/robot/IAD). In one example, one or more sensitive elements are specifically calibrated to one or more particular design features, such as environmental features (e.g., weight, height, etc.). When a stimuli provided to the sensing element is outside the calibration range, the sensitive element provides output via the antenna to a controller that submits output to a second device. The second device is then designed and capable of responding to the sensitive element. This may serve usefully, for example, for safety measures when working with large or heavy objects, such that a second device carrying or moving the large or heavy object is, in a sense, made capable of knowing when in contact with an operator that has one or more sensitive devices when the sensitive devices comes in contact with the large or heavy object.

Sensitive elements herein provide an operator and/or intelligent system with a functional ability to sense, respond, as well as interact with an operator/human/environment/device. In a predetermined manner, a plurality of elements of one or a variety of sensor types form a network with smart actuation and/or efficient control algorithms/instructions to identify types and strengths of stimuli and to initiate response and action.

Additional objects, advantages and novel features of the invention as set forth in the description, will be apparent to one skilled in the art after reading the foregoing detailed description or may be learned by practice of the invention. The objects and advantages of the invention may be realized and attained by means of the instruments and combinations particularly pointed out here.

What is claimed is:

1. A sensitive device comprising:
a non-rigid substrate;
one or more piezoelectric units supported by the substrate;
an antenna excited by outputs from the one or more piezoelectric units.

2. The sensitive device of claim 1, wherein the outputs are processed by a controller.

3. The sensitive device of claim 1, wherein the one or more piezoelectric units include piezoelectric composites provided as fibers, multilayer composites or unimorphs.

4. The sensitive device of claim 1, wherein the substrate includes an elastomeric polymer.

5. The sensitive device of claim 1, wherein the substrate includes silicone rubber.

6. The sensitive device of claim 2, wherein the outputs provide an estimate of interaction between the device and its environment.

7. The sensitive device of claim 1 further comprising an electrical source for driving the one or more piezoelectric units.

8. The sensitive device of claim 1, wherein the one or more piezoelectric units are multi functional.

9. The sensitive device of claim 1, wherein the one or more piezoelectric units are transducers.

10. A sensitive device comprising:
a non-rigid substrate;
one or more piezoelectric units supported by the substrate;
an antenna excited by outputs from the one or more piezoelectric units;
a controller in operable communication with the antenna, wherein the controller receives output signals from the antenna.

11. The sensitive device of claim 10, wherein the controller is a supervisory decision-making controller.

12. The sensitive device of claim 10, wherein the one or more piezoelectric units include piezoelectric composites provided as fibers, multilayer composites or unimorphs.

13. The sensitive device of claim 10, wherein the substrate includes an elastomeric polymer.

14. The sensitive device of claim 13, wherein the elastomeric polymer includes silicone rubber.

15. The sensitive device of claim 10, wherein the controller provides an estimate of interaction between the device and its environment.

16. The sensitive device of claim 10, wherein an electrical source drives the one or more piezoelectric units.

17. The sensitive device of claim 10, wherein the one or more piezoelectric units are multi functional.

18. The sensitive device of claim 10, wherein the piezoelectric units are transducers.

19. The sensitive device of claim 10, wherein the controller is a supervisory decision making controller.

20. The sensitive device of claim 10, wherein the one or more piezoelectric units are embedded in the compliant substrate.

21. The sensitive device of claim 10, wherein the piezoelectric units are responsive to one or more stimuli including force, pressure, deformation, displacement, acceleration, vibration, sound, strain, motion, heat, voltage.

22. The sensitive device of claim 10, wherein the controller comprises instructions for processing signals received by the antenna and for providing input to the substrate.

23. A control system comprising:
an antenna for receiving wireless communications from a sensing device, the wireless communications representative of outputs from one or more piezoelectric units, the antenna located in the sensing device;
a controller, a portion of which contains instructions for processing signals received by the antenna and for providing input to the sensing device.

24. The control system of claim 23, wherein the controller is an impedance controller.

25. The control system of claim 23, wherein the instructions make use of a Kalman filter for estimations.

26. The control system of claim 23, wherein the instructions include compliance characteristics for the sensing device.

27. The control system of claim 23, wherein the control system provides work path plans adapted to the sensing device.

28. A method comprising:
providing a sensing device, the sensing device comprising a non-rigid substrate with one or more piezoelectric units and an antenna, wherein the antenna is excited by outputs from the one or more piezoelectric units;
processing signals received by the antenna using a controller containing instructions.

29. The method of claim 28 further comprising providing input to the sensing device from the controller.

30. The method of claim 28, wherein instructions rely on a Kalman filter.

31. The method of claim 28, wherein the controller is an impedance controller

32. The method of claim 28, wherein the instructions allow the sensing device to interact with an environment.

33. The method of claim 28, wherein instructions allow output from the controller to be provided to a second device.

34. The method of claim 33, wherein the second device is a robot, assist device or intelligent assist device.
